(19) United States
(12) Patent Application Publication
(10) Pub. No.: US 2026/0353832 A1
(43) Pub. Date: Nov. 5, 2026

(54) IMAGE SENSING DEVICE

(71) Applicant: SK hynix Inc., Icheon-si (KR)

(72) Inventor: Han Seung LEE, Icheon-si (KR)

(21) Appl. No.: 19/386,044

(22) Filed: Nov. 11, 2025

(30) Foreign Application Priority Data
May 2, 2025 (KR) 10-2025-0058413

(51) Int. Cl. H10F 39/00; G01S 7/481; G01S 17/89; H10F 39/18

(52) U.S. Cl. CPC H10F 39/806; G01S 7/4816; G01S 17/89; H10F 39/184; H10F 39/8063; H10F 39/807

(57) ABSTRACT

Image sensing devices are disclosed. In an embodiment, an image sensing device includes: at least one photoelectric conversion region disposed within a substrate; a plurality of first trench structures having a first length extending from a first surface of the substrate into the substrate, each of the plurality of first trench structures being arranged to at least partially overlap the photoelectric conversion region in plan view; a second trench structure having a second length extending from the first surface of the substrate into the substrate and disposed between the first trench structures; an overcoating layer disposed over the first surface of the substrate; and a plurality of microlenses disposed over the overcoating layer. The second length is longer than the first length; and the microlenses overlap the first trench structures and the second trench structure in plan view.

### PRIORITY CLAIM AND CROSS-REFERENCE TO RELATED APPLICATION

This patent document claims the priority and benefits of Korean patent application No. 10-2025-0058413, filed on May. 2, 2025, the disclosure of which is incorporated herein by reference in its entirety as part of the disclosure of this patent document.

### TECHNICAL FIELD

The technology and implementations disclosed in this patent document generally relate to an image sensing device.

### BACKGROUND

An image sensing device captures optical images by converting light into electrical signals using a photosensitive semiconductor material that reacts to light. With advancements in industries such as automotive, medical, computer and communication industries, the demand for high-performance image sensing devices is growing across various fields such as smartphones, digital cameras, game machines, IoT (Internet of Things), robots, security cameras and medical micro cameras.

The image sensing device may be roughly divided into charge coupled device (CCD) image sensing devices and complementary metal oxide semiconductor (CMOS) image sensing devices.

### SUMMARY

Various embodiments of the disclosed technology relate to an image sensing device that includes a single-photon avalanche diode (SPAD) pixel with improved infrared light reception efficiency. Some embodiments of the disclosed technology provide an image sensing device that includes a trench structure to increase light reception efficiency, and a method for manufacturing the same.

In an embodiment of the disclosed technology, an image sensing device may include: at least one photoelectric conversion region disposed within a substrate and configured to generate photocharges in response to incident light; a plurality of first trench structures having a first length extending from a first surface of the substrate into the substrate, each of the plurality of first trench structures being arranged to at least partially overlap the photoelectric conversion region in plan view; a second trench structure having a second length extending from the first surface of the substrate into the substrate and disposed between the first trench structures; an overcoating layer disposed over the first surface of the substrate; and a plurality of microlenses disposed over the overcoating layer. The second length may be longer than the first length, and the microlenses may overlap the first trench structures and the second trench structure in plan view (e.g., in plan view corresponding to the first surface of the substrate). In some implementations, the second trench structure is disposed between groups of the first trench structures.

In some implementations, the image sensing device may further include: a third trench structure disposed between adjacent photoelectric conversion regions.

In some implementations, the first trench structure may include a single layer formed of one or more materials.

In some implementations, the second trench structure may include a plurality of layers, each of the plurality of layers being formed of one or more materials.

In some implementations, the plurality of layers in the second trench structure may include a metal layer.

In some implementations, the third trench structure may extend from the first surface of the substrate to a second surface facing or opposite to the first surface.

In some implementations, the third trench structure may include a plurality of layers.

In some implementations, the plurality of layers in the third trench structure may include a metal layer.

In some implementations, the plurality of layers in the third trench structure may include an air layer. In some implementations, the term “air layer” refers to a layer that is structured to contain air.

In some implementations, the plurality of microlenses may be arranged in a (M × N) matrix pattern over the first surface of the substrate, wherein each of M and N is an integer of 2 or greater.

In some implementations, each of the plurality of microlenses may overlap the first trench structures.

In some implementations, the photoelectric conversion region may include a single-photon avalanche diode (SPAD).

In some implementations, the plurality of first trench structures may be arranged in a honeycomb pattern in plan view corresponding to the first surface of the substrate.

In some implementations, the plurality of first trench structures may be arranged in a (M × N) matrix pattern in plan view corresponding to the first surface of the substrate, wherein each of M and N is an integer of 2 or greater.

In some implementations, the image sensing device may further include: a grid structure disposed between adjacent overcoating layers.

In some implementations, the photoelectric conversion region may include an impurity region doped with impurities of a conductivity type different from a conductivity type of the substrate.

In some implementations, the photoelectric conversion region may include: an impurity region in contact with a second surface facing or opposite to the first surface of the substrate, the impurity region being doped with a higher concentration of impurities than the substrate.

In another embodiment of the disclosed technology, an image sensing device may include: a photoelectric conversion region disposed within a substrate and configured to generate photocharges in response to incident light; a plurality of first trench structures arranged to at least partially overlap the photoelectric conversion region in plan view, the plurality of first trench structures being arranged in a matrix pattern over a first surface of the substrate; a second trench structure disposed between the first trench structures; and a third trench structure arranged to surround the photoelectric conversion region. Each of the plurality of first trench structures may extend from the first surface of the substrate into the substrate to a first depth, and the second trench structure may extend from the first surface of the substrate into the substrate to a second depth greater than the first depth. The third trench structure may extend from the first surface of the substrate into the substrate to a third depth greater than the second depth.

In some implementations, the image sensing device may further include: an overcoating layer disposed over the first surface of the substrate; and a plurality of microlenses disposed over the overcoating layer and arranged in a matrix pattern over the first surface of the substrate.

In some implementations, the third trench structure may include an air layer.

It is to be understood that both the foregoing general description and the following detailed description of the disclosed technology are illustrative and explanatory and are intended to provide further explanation of the disclosed technology as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some embodiments of the disclosed technology.

FIG. 2A is a diagram illustrating an example of one surface of a pixel array based on an embodiment of the disclosed technology.

FIG. 2B is a diagram illustrating an example of one surface of a pixel array based on another embodiment of the disclosed technology.

FIG. 3 is a cross-sectional view illustrating an example of the pixel array based on an embodiment of the disclosed technology.

FIG. 4 is a diagram illustrating an example of one surface of a pixel array based on another embodiment of the disclosed technology.

FIG. 5 is a cross-sectional view illustrating an example of the pixel array based on another embodiment of the disclosed technology.

FIG. 6 is a diagram illustrating an example of one surface of a pixel array based on another embodiment of the disclosed technology.

FIG. 7 is a diagram illustrating an example of one surface of a pixel array based on another embodiment of the disclosed technology.

### DETAILED DESCRIPTION

This patent document provides implementations and examples of an image sensing device having a trench structure to increase light reception efficiency. The image sensing device implemented based on some embodiments may be configured to substantially address one or more technical or engineering issues and to mitigate limitations or disadvantages encountered in some existing image sensing devices. Some implementations of the disclosed technology relate to a single-photon avalanche diode (SPAD) pixel with improved infrared light reception efficiency. In recognition of the issues above, the disclosed technology may provide an image sensing device that can improve the light reception efficiency for infrared light while minimizing optical crosstalk between adjacent pixels. In addition, the image sensing device may secure an optical path of incident light to minimize degradation in sensitivity to the infrared light, and may reduce process complexity.

Reference will now be made in detail to the embodiments of the disclosed technology, examples of which are illustrated in the accompanying drawings. Wherever possible, like reference numerals and characters are used throughout the accompanying drawings to refer to like components. While the disclosed technology is susceptible to various modifications and alternative forms, specific embodiments thereof are shown by way of example in the drawings. However, the disclosed technology should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

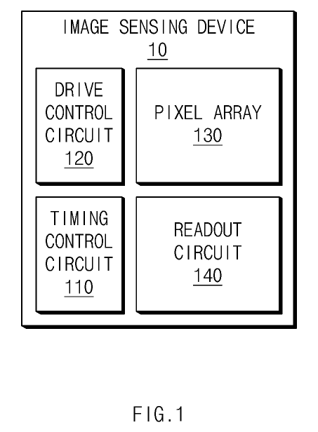

FIG. 1 is a block diagram illustrating an example of an image sensing device 10 based on some embodiments of the disclosed technology.

Referring to FIG. 1, the image sensing device 10 according to an exemplary embodiment of the disclosed technology may include a timing control circuit 110, a drive control circuit 120, a pixel array 130, and a readout circuit 140. The constituent components of the image sensing device 10 illustrated in FIG. 1 are discussed by way of example only, and this patent document encompasses numerous other changes, substitutions, variations, alterations, and modifications. In some embodiments described, the word “pixel” can be used to indicate an image sensing pixel that is structured to detect incident light to generate electrical signals carrying images in the incident light. For example, the image sensing device 10 may be a complementary metal oxide semiconductor (CMOS) image sensor configured to convert incident light into an electrical signal.

The timing control circuit 110 may generate a timing signal to control the operations of the drive control circuit 120 and the readout circuit 140. In some implementations, the timing control circuit 110 may generate a timing signal in response to a request from an external processor (e.g., an image signal processor ISP). In some implementations, the timing control circuit 110 may include a logic control circuit, a phase-locked loop (PLL) circuit, a communication interface circuit, and the like.

The drive control circuit 120 may drive pixels (PXs) of the pixel array 130 in response to a timing signal output from the timing control circuit 110. The drive control circuit 120 may select and control pixels (PXs) included in at least one row line from among a plurality of row lines of the pixel array 130. The drive control circuit 120 may generate a row selection signal to select at least one row from among the plurality of rows. The drive control circuit 120 may sequentially enable a pixel reset signal and a transfer signal for pixels (PXs) corresponding to at least one selected row. Accordingly, an analog reference signal and an image signal generated from each of the pixels (PXs) of the selected row may be sequentially transmitted to the readout circuit 140. The reference signal may be an electrical signal provided to the readout circuit 140 when a floating diffusion region (FD) of each pixel is reset to a power-supply voltage (VDD). The image signal may be an electrical signal provided to the readout circuit 140 when photocharges generated by each pixel are accumulated in the floating diffusion region (FD). The reference signal indicating unique pixel noise of each pixel, and the image signal indicating the intensity of incident light may be collectively referred to as a pixel signal when appropriate.

The pixel array 130 may include a plurality of pixels (PXs) arranged in rows and columns. In one example, the plurality of pixels (PXs) may be arranged in a two-dimensional (2D) pixel array including rows and columns. In another example, the plurality of pixels (PXs) may also be arranged in a three-dimensional (3D) pixel array including rows and columns. The plurality of pixels (PXs) may convert an optical signal into an electrical signal on a pixel basis or a pixel group basis, and may output a pixel signal. Here, the pixels in a pixel group of the pixel array 130 may share at least certain internal circuitry. The pixel array 130 may receive driving signals including a row selection signal, a pixel reset signal, a transfer signal, etc. from the drive control circuit 120. Upon receiving the driving signals, the corresponding pixels (PXs) in the pixel array 130 may be activated to perform the operations corresponding to the row selection signal, the pixel reset signal, and the transfer signal.

The readout circuit 140 may detect a pixel signal output from the pixel array 130 under the control of the timing control circuit 110, and may output the detected pixel signal as image data. The image data may be digital data generated by performing an analog-to-digital conversion process on an analog pixel signal. To this end, the readout circuit 140 may include a correlated double sampler (CDS) for performing correlated double sampling on pixel signals output from the pixel array 130. In addition, the readout circuit 140 may include an analog-to-digital converter (ADC) for converting signals output from the correlated double sampler (CDS) into digital signals to generate pixel data. In addition, the readout circuit 140 may include a buffer circuit for temporarily storing pixel data output from the analog-to-digital converter (ADC) and outputting the stored pixel data to the outside under the control of the timing control circuit 110. The correlated double sampler (CDS) may remove the undesired offset value of pixels by comparing pixel output voltages obtained before and after photocharges generated by incident light are accumulated in the floating diffusion region (FD) so that only pixel output voltages based on the incident light can be measured. The readout circuit 140 may sequentially sample and hold voltage levels of the reference signal and the image signal, which are provided to each of a plurality of column lines from the pixel array 130. That is, the readout circuit 140 may sample and hold the voltage levels of the reference signal and the image signal which correspond to each of the columns of the pixel array 130. The readout circuit 140 may convert a correlated double sampler (CDS) signal, which is an analog signal for each column, into a digital signal, and may output the digital signal for each column. The readout circuit 140 may temporarily hold image data for each column, and may output the image data to, for example, an image processing device (not shown).

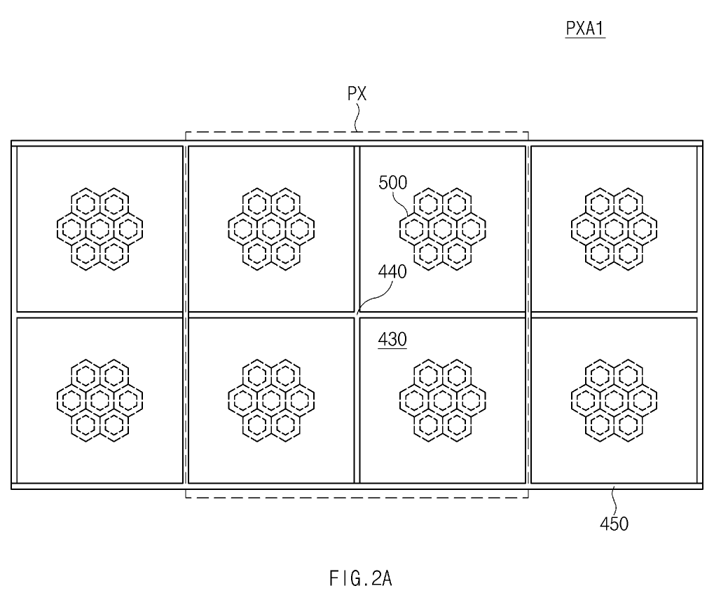

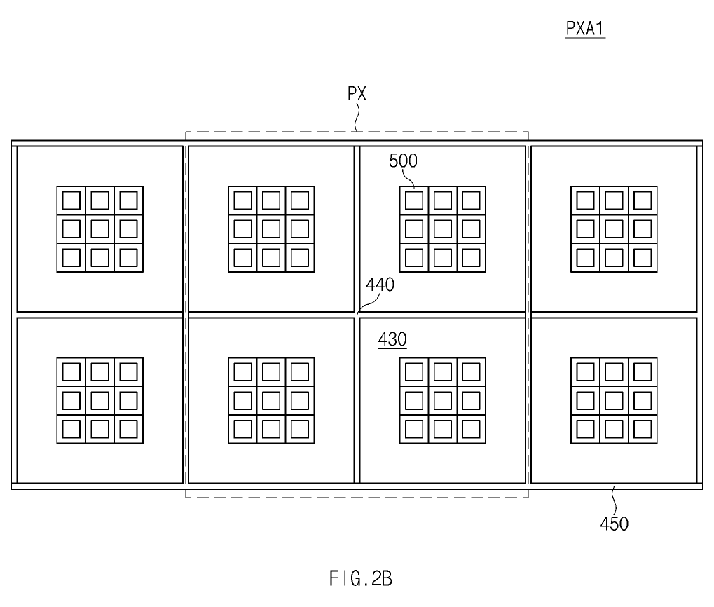

FIG. 2A is a diagram illustrating an example of one surface of a pixel array (PXA1) based on an embodiment of the disclosed technology.

FIG. 2B is a diagram illustrating an example of one surface of a pixel array based on another embodiment of the disclosed technology.

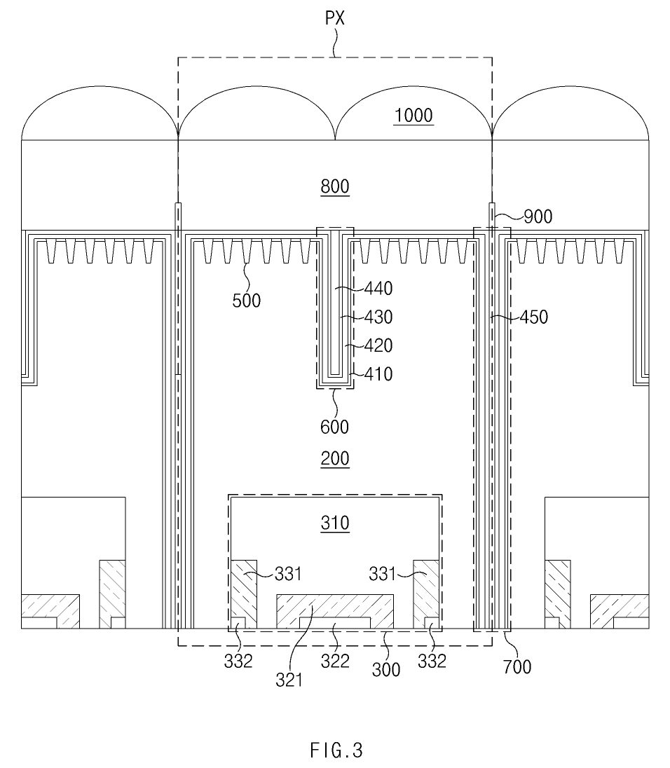

FIG. 3 is a cross-sectional view illustrating an example of the pixel array (PXA1) based on an embodiment of the disclosed technology.

The image sensing device based on an embodiment of the disclosed technology will hereinafter be described with reference to FIGS. 2A and 3.

The pixel array (PXA1) may include a plurality of unit pixels (PXs). Each unit pixel (PX) may include a substrate 200, a photoelectric conversion region 300 supported by the substrate 200, (e.g., being disposed within the substrate 200), first trench structures 500 that are supported by the substrate to at least partially overlap the photoelectric conversion region 300, a second trench structure 600 supported by the substrate 200 and extending from one surface of the substrate 200 and located between the first trench structures 500, and third trench structures 700 supported by the substrate 200 surrounding the photoelectric conversion region 300. In some embodiments, the term “trench” or “trench structure” refers to a recessed region formed in a substrate, and may include configurations in which the recessed region is filled or partially filled with one or more materials such as dielectric materials, metal, or air.

In addition, each unit pixel (PX) may include at least one overcoating layer 800 disposed over one surface of the substrate 200, a grid structure 900 disposed between the overcoating layers 800, and a plurality of microlenses 1000 disposed over the overcoating layer 800.

For example, the substrate 200 may be or include a monocrystalline silicon substrate. The substrate 200 may be or include a P-type or N-type bulk substrate, may be or include a substrate formed by growing a P-type or N-type epitaxial layer on the P-type bulk substrate, or may be or include a substrate formed by growing a P-type or N-type epitaxial layer on the N-type bulk substrate. In some embodiments described below, it is assumed that the substrate 200 is a silicon substrate doped with P-type impurities for convenience of description.

The photoelectric conversion region 300 may generate photocharges corresponding to incident light that has passed through the microlenses 1000 and the overcoating layer 800. The incident light may be reflected and scattered by the first trench structures 500, the second trench structure 600, and the third trench structures 700, thereby reaching the photoelectric conversion region 300. For example, the incident light may be infrared light. An image sensor that receives infrared light may improve light reception efficiency of the photoelectric conversion region 300 by extending an optical path of the incident light through scattering.

The photoelectric conversion region 300 may be implemented as a photodiode, a phototransistor, a photogate, a pinned photodiode or a combination thereof. Hereinafter, for illustrative purposes, it is assumed that the photoelectric conversion region 300 is a photodiode.

A light detection and ranging (LiDAR) image sensor including a single-photon avalanche diode (SPAD) may receive infrared light, and a small amount of secondary photons may be generated during the avalanche operation due to hot-carrier luminescence, which can cause optical crosstalk between adjacent pixels. To mitigate this effect, a quenching operation is performed after the avalanche operation to stop the avalanche current and stabilize the SPAD.

In some implementations, the photoelectric conversion region 300 may be a single-photon avalanche diode (SPAD) that detects a single photon of incident light and generates a voltage pulse corresponding to the detected single photon.

The single-photon avalanche diode (SPAD) may operate as a photodiode including a photosensitive P-N junction. Since avalanche breakdown is triggered by a single photon incident in a Geiger mode in which a reverse bias voltage caused by a cathode-anode voltage higher than a breakdown voltage occurs, the SPAD may generate a voltage pulse. In this way, the process in which avalanche breakdown is triggered by a single photon and a voltage pulse is generated will hereinafter be defined as an avalanche process.

After the avalanche breakdown is triggered, the SPAD may perform a quenching and recharge operation in which an external circuit connected to the SPAD initializes a voltage of the SPAD to a quenching voltage so that the SPAD returns to the Geiger mode.

The photoelectric conversion region 300 may be a region formed within a silicon substrate 200 doped with P-type impurities. In more detail, the photoelectric conversion region 300 may include regions doped with N-type impurities and regions doped with P-type impurities. The photoelectric conversion region 300 may be formed through ion implantation.

The photoelectric conversion region 300 may include a first N-well region 310 doped with N-type impurities; a first P-well region 321 doped with P-type impurities and configured to contact the first N-well region 310; a P-type contact region 322 contacting the first P-well region 321 and doped with a higher concentration of P-type impurities than the first P-well region 321; a second N-well region 331 disposed within the first N-well region 310 and including N-type impurities; and an N-type contact region 332 contacting the second N-well region 331 and including a higher concentration of N-type impurities than the second N-well region 331.

The P-type contact region 322 and the N-type contact region 332 may be regions that are in contact with an external contact (not shown) formed below the substrate 200.

The first trench structures 500 may extend from one surface of the substrate 200 to the other surface of the substrate 200. The first trench structures 500 may scatter incident light received through the overcoating layer 800, and may increase the optical path of the incident light. When the optical path of the incident light increases, the time for which infrared light stays in the substrate 200 increases, resulting in an increase in the light reception efficiency of the photoelectric conversion region 300.

The first trench structures 500 may be regions formed by etching one surface of the substrate 200 and forming an insulation material or the like in the etched regions. For example, each of the first trench structures 500 may include silicon oxide or the like. According to another embodiment, each of the first trench structures 500 may include a metal or a metal nitride.

Each of the first trench structures 500 may include a single material within the trench. In other words, the first trench structure 500 may be formed of a single material layer.

Each of the first trench structures 500 may have a honeycomb structure with respect to one surface of the substrate 200(see in FIG. 2A). The honeycomb structure may be a structure in which hexagonal patterns are repeatedly arranged. However, the shape of the first trench structures 500 with respect to one surface of the substrate 200 is not limited thereto, and any shape that can scatter incident light to increase the optical path may be used. For example, the first trench structures 500 with respect to one surface of the substrate 200 may be formed in various shapes such as a circular shape, a polygonal shape, a hash shape, and the like.

A plurality of first trench structures 500 overlapping a single photoelectric conversion region 300 may be arranged in a (M × M) matrix pattern(each of M and N is an integer of 2 or greater)(see in FIG. 2B). In other words, four first trench structures 500 may be arranged over one photoelectric conversion region 300.

The second trench structure 600 may extend from one surface of the substrate 200 to the other surface of the substrate 200. The second trench structure 600 may include a plurality of layers.

The second trench structure 600 may include a protective layer 410, a first anti-reflection layer 420, a second anti-reflection layer 430, and a first conductive layer 440.

The protective layer 410 may be a layer including a metal oxide. The protective layer 410 may serve to electrically isolate the first conductive layer 440 from the substrate 200. As the protective layer 410 is formed, defects or impurities on the surface of the second trench structure 600 may be suppressed. For example, the protective layer 410 may include aluminum oxide.

The protective layer 410 included in the second trench structure 600 may extend along the bottom and side surfaces of the second trench structure 600.

The first anti-reflection layer 420 may include an oxide material. The first anti-reflection layer 420 may include a material having a high dielectric constant (i.e., a high permittivity). The first anti-reflection layer 420 may serve to electrically isolate the first conductive layer 440 from the substrate 200. For example, the first anti-reflection layer 420 may include hafnium oxide.

The first anti-reflection layer 420 included in the second trench structure 600 may be disposed over the protective layer 410 that extends along the bottom and side surfaces of the second trench structure 600.

The second anti-reflection layer 430 may include an oxide material. The second anti-reflection layer 430 may serve to guide incident light into the substrate 200 by using a difference in refractive index. For example, the second anti-reflection layer 430 may include silicon oxide.

The second anti-reflection layer 430 included in the second trench structure 600 may be disposed between the first anti-reflection layer 420 and the first conductive layer 440.

The first conductive layer 440 may include a metal material. For example, the first conductive layer 440 may include tungsten. As the first conductive layer 440 is formed, incident light may be guided to be reflected into the substrate 200. According to an embodiment, a control voltage may be applied to the first conductive layer 440 to reduce a leakage current within the unit pixel (PX).

According to an embodiment, one surface of the first conductive layer 440 included in the second trench structure 600 may be formed to contact the overcoating layer 800.

The length (or depth) of the second trench structure 600 with respect to one surface of the substrate 200 may be referred to as a second length. Similarly, the length (or depth) of the first trench structure 500 with respect to one surface of the substrate 200 may be referred to as a first length. According to an embodiment, the second length may be longer than the first length.

The third trench structure 700 may have a shape that extends from one surface of the substrate 200 to the other surface of the substrate 200. The third trench structure 700 may include a plurality of layers.

The third trench structure 700 may include a protective layer 410, a first anti-reflection layer 420, a second anti-reflection layer 430, and a second conductive layer 450.

The protective layer 410 may be a layer including a metal oxide. The protective layer 410 may serve to electrically isolate the second conductive layer 450 from the substrate 200. As the protective layer 410 is formed, defects or impurities on the surface of the second trench structure 600 may be suppressed. For example, the protective layer 410 may include aluminum oxide.

The protective layer 410 included in the third trench structure 700 may extend from one surface of the substrate 200 toward the other surface of the substrate 200, and may be formed to surround the side surfaces of the third trench structure 700.

The first anti-reflection layer 420 may include an oxide material. The first anti-reflection layer 420 may include a material having a high dielectric constant (i.e., a high permittivity). The first anti-reflection layer 420 may serve to electrically isolate the second conductive layer 450 from the substrate 200. For example, the first anti-reflection layer 420 may include hafnium oxide.

The first anti-reflection layer 420 included in the third trench structure 700 may be formed to contact the protective layer 410 that is formed along the side surfaces of the third trench structure 700.

The second anti-reflection layer 430 may include an oxide material. The second anti-reflection layer 430 may serve to guide incident light into the substrate 200 by using a difference in refractive index. For example, the second anti-reflection layer 430 may include silicon oxide.

The second anti-reflection layer 430 included in the third trench structure 700 may be disposed between the first anti-reflection layer 420 and the second conductive layer 450.

The second conductive layer 450 may include a metal material. For example, the second conductive layer 450 may include tungsten. According to an embodiment, a control voltage may be applied to the second conductive layer 450 to reduce a leakage current within the unit pixel (PX).

The second conductive layer 450 included in the third trench structure 700 may have a shape that extends from one surface of the substrate 200 to the other surface of the substrate 200.

The length (or depth) of the third trench structure 700 on the one surface of the substrate 200 may be referred to as a third length. In addition, the length of the second trench structure 600 on the one surface of the substrate 200 may be referred to as a second length. According to an embodiment, the third length may be longer than the second length.

As the third trench structure 700 extends from one surface of the substrate 200 to the other surface of the substrate 200, crosstalk between adjacent photoelectric conversion regions 300 may be minimized or prevented.

According to an embodiment, the first conductive layer 440 may be arranged to contact the second conductive layer 450. When the first conductive layer 440 and the second conductive layer 450 are in contact with each other, a voltage may be simultaneously applied to both the first conductive layer 440 and the second conductive layer 450.

The overcoating layer 800 may be a region through which incident light passes, and may be disposed between the substrate 200 and the microlenses 1000. The overcoating layer 800 may include the same material as the microlens 1000.

The grid structure 900 may be a region disposed between adjacent overcoating layers 800, and may serve to minimize or prevent crosstalk between adjacent unit pixels (PXs). For example, the grid structure 900 may include a metal material.

The microlenses 1000 may be disposed over the overcoating layer 800, and may guide incident light into the substrate 200.

The unit pixel (PX) may include a plurality of microlenses 1000. For example, the microlenses 1000 may be arranged in a (M × N) matrix pattern over the overcoating layer 800(each of M and N is an integer of 2 or greater). The microlenses 1000 may include the same material as the overcoating layer 800. For example, the microlenses 1000 may include a light transmissive polymer material.

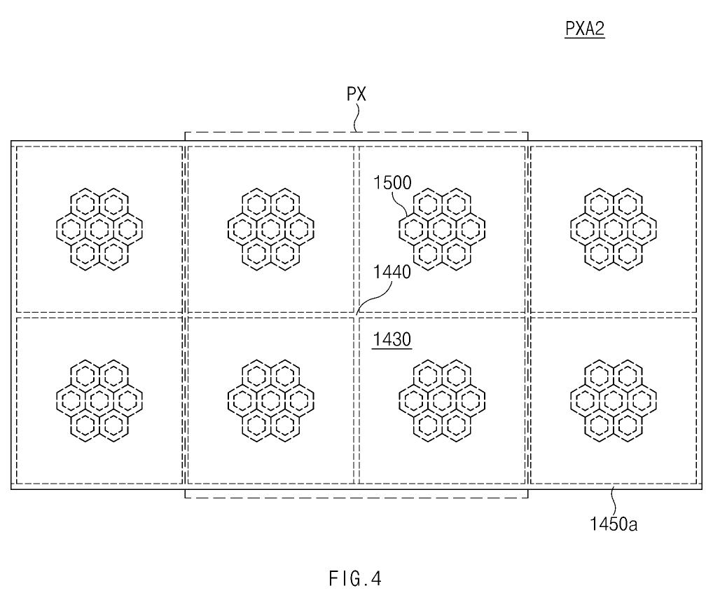

FIG. 4 is a diagram illustrating an example of one surface of a pixel array (PXA2) based on another embodiment of the disclosed technology.

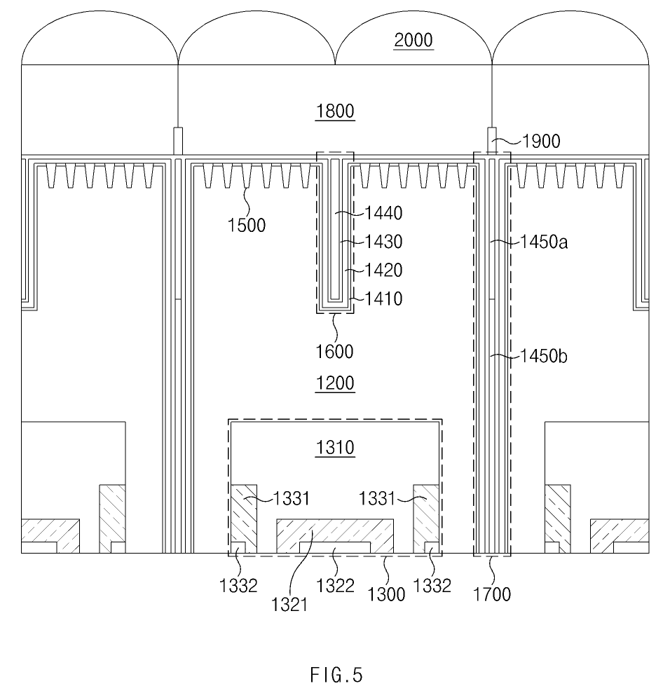

FIG. 5 is a cross-sectional view illustrating an example of the pixel array (PXA2) based on another embodiment of the disclosed technology.

The image sensing device based on an embodiment of the disclosed technology will hereinafter be described with reference to FIGS. 4 and 5.

The pixel array (PXA2) may include a plurality of unit pixels (PXs). Each unit pixel (PX) may include a substrate 1200, a photoelectric conversion region 1300 disposed within the substrate 1200, first trench structures 1500 that at least partially overlap the photoelectric conversion region 1300, a second trench structure 1600 extending from one surface of the substrate 1200 and located between the first trench structures 500, and third trench structures 1700 surrounding the photoelectric conversion region 1300.

In addition, each unit pixel (PX) may include at least one overcoating layer 1800 disposed over one surface of the substrate 1200, a grid structure 1900 disposed between the overcoating layers 1800, and a plurality of microlenses 2000 disposed over the overcoating layer 1800.

The remaining structures of the image sensing device discussed above with reference to FIGS. 4 and 5 except for a third trench structure 1700 are substantially the same as the image sensing device described with reference to FIGS. 2A and 3, and redundant description is omitted for brevity.

The following description will focus on the second trench structure 1600 and the third trench structure 1700.

The second trench structure 1600 may include a protective layer 1410, a first anti-reflection layer 1420, a second anti-reflection layer 1430, and a first conductive layer 1440.

Unlike the example configuration described with reference to FIGS. 2A and 3, the second anti-reflection layer 1430 may be formed to cover an upper portion of the first conductive layer 1440. Accordingly, at least a portion of the second anti-reflection layer 1430 may be disposed between the first conductive layer 1440 and the overcoating layer 1800.

The third trench structure 1700 may include a protective layer 1410, a first anti-reflection layer 1420, a second anti-reflection layer 1430, an air layer 1450a, and a second conductive layer 1450b.

Unlike the example configuration described with reference to FIGS. 2A and 3, the second anti-reflection layer 1430 may be formed to cover an upper portion of the air layer 1450a. Accordingly, at least a portion of the second anti-reflection layer 1430 may serve as a capping layer for the air layer 1450a.

The air layer 1450a may be a layer containing air. As the air layer 1450a having a low refractive index is formed, incident light directed toward the third trench structure 1700 may be totally reflected into the unit pixel (PX). Accordingly, formation of the air layer 1450a may enhance the light reception efficiency of the photoelectric conversion region 1300. The second conductive layer 1450b disposed below the air layer 1450a may include, for example, a metal material.

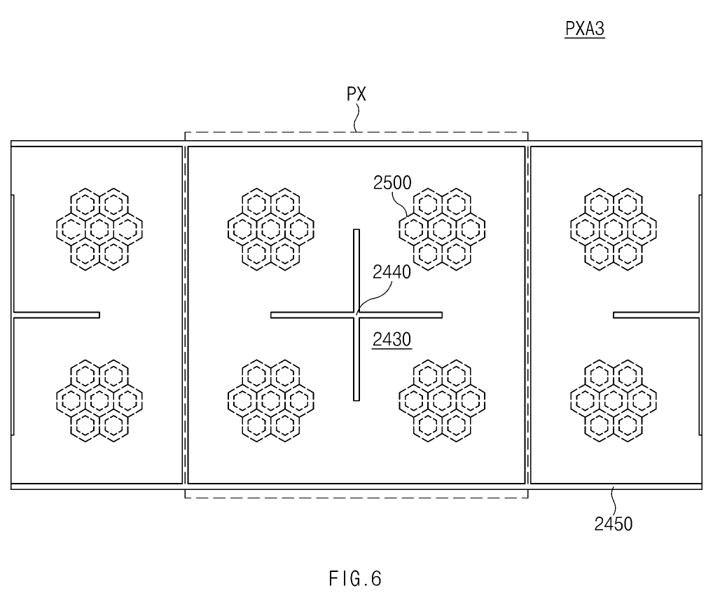

FIG. 6 is a diagram illustrating an example of one surface of a pixel array (PXA3) based on another embodiment of the disclosed technology.

Referring to FIG. 6, a first conductive layer 2440 included in a second trench structure (not shown) may be formed separately from a second conductive layer 2450 included in a third trench structure (not shown). In other words, in an embodiment, the second trench structure (not shown) and the third trench structure (not shown) may be electrically isolated from each other.

As the first conductive layer 2440 and the second conductive layer 2450 are formed to be separated from each other, the area capable of receiving incident light may be increased, and the amount of light reflected by the second trench structure (not shown) may decrease, thereby increasing the light reception efficiency.

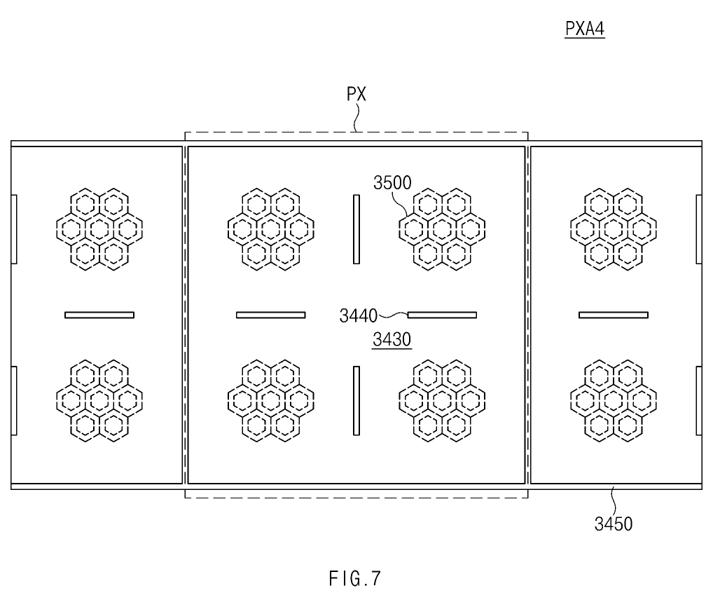

FIG. 7 is a diagram illustrating an example of one surface of a pixel array (PXA4) based on another embodiment of the disclosed technology.

Referring to FIG. 7, a plurality of first conductive layers 3440 included in the second trench structure (not shown) may be formed. In addition, according to the embodiment of FIG. 7, the first conductive layer 3440 may be formed separately from the second conductive layer 3450 included in the third trench structure (not shown). In some implementations, as the shape of the first conductive layer 3440 is changed, the incident path and the reflection path of the incident light can be adjusted.

The structures and operations of pixels, positions of impurity regions, doping concentrations, etc. are merely examples, and may vary within the range to which the technical idea of the disclosed technology can be applied.

As is apparent from the above description, the image sensing device based on some embodiments of the disclosed technology may improve the light reception efficiency for infrared light while minimizing optical crosstalk between adjacent pixels. In addition, the image sensing device based on some embodiments of the disclosed technology may secure an optical path of incident light to minimize degradation in sensitivity to the infrared light, and may reduce process complexity.

The embodiments of the disclosed technology may provide a variety of effects capable of being directly or indirectly recognized through the above-mentioned patent document.

Those skilled in the art will appreciate that the disclosed technology may be carried out in other specific ways than those set forth herein.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a substrate;
photoelectric conversion regions supported by the substrate;
a plurality of first trench structures configured to overlap at least a portion of the photoelectric conversion regions and having a first length extending from a first surface of the substrate into the substrate;
a second trench structure having a second length extending from the first surface of the substrate into the substrate and disposed between the first trench structures;
an overcoating layer disposed over the first surface of the substrate; and
a plurality of microlenses disposed over the overcoating layer,
wherein:
the second length is longer than the first length; and
the microlenses overlap the first trench structures and the second trench structure.

2. The image sensing device according to claim 1, further comprising:
a third trench structure disposed between adjacent photoelectric conversion regions.

3. The image sensing device according to claim 1, wherein:
the first trench structure includes a single layer formed of one or more materials.

4. The image sensing device according to claim 1, wherein:
the second trench structure includes a plurality of layers, each of the plurality of layers being formed of one or more materials.

5. The image sensing device according to claim 4, wherein:
the plurality of layers in the second trench structure includes a metal layer.

6. The image sensing device according to claim 2, wherein:
the third trench structure extends from the first surface of the substrate to a second surface of the substrate facing or opposite to the first surface.

7. The image sensing device according to claim 2, wherein:
the third trench structure includes a plurality of layers, each of the plurality of layers being formed of one or more materials.

8. The image sensing device according to claim 7, wherein:
the plurality of layers in the third trench structure includes a metal layer.

9. The image sensing device according to claim 7, wherein:
the plurality of layers in the third trench structure includes an air layer.

10. The image sensing device according to claim 1, wherein:
the plurality of microlenses is arranged in a (M × N) matrix pattern over the first surface of the substrate,
wherein each of M and N is an integer of 2 or greater.

11. The image sensing device according to claim 10, wherein:
each of the plurality of microlenses is arranged to overlap the first trench structures.

12. The image sensing device according to claim 1, wherein:
the photoelectric conversion region includes a single-photon avalanche diode (SPAD).

13. The image sensing device according to claim 1, wherein:
the plurality of first trench structures is arranged in a honeycomb pattern in plan view corresponding to the first surface of the substrate.

14. The image sensing device according to claim 1, wherein:
the plurality of first trench structures is arranged in a (M × N) matrix pattern in plan view corresponding to the first surface of the substrate,
wherein each of M and N is an integer of 2 or greater.

15. The image sensing device according to claim 1, further comprising:
a grid structure disposed between adjacent overcoating layers.

16. The image sensing device according to claim 1, wherein:
the photoelectric conversion region includes an impurity region doped with impurities of a conductivity type different from a conductivity type of the substrate.

17. The image sensing device according to claim 1, wherein the photoelectric conversion region includes:
an impurity region in contact with a second surface facing or opposite to the first surface of the substrate, the impurity region being doped with a higher concentration of impurities than the substrate.

18. An image sensing device comprising:
a photoelectric conversion region disposed within a substrate;
a plurality of first trench structures arranged to at least partially overlap at least a portion of the photoelectric conversion region, the plurality of first trench structures being arranged in a matrix pattern over a first surface of the substrate;
a second trench structure disposed between the first trench structures; and
a third trench structure arranged to surround the photoelectric conversion region,
wherein each of the plurality of first trench structures extends from the first surface of the substrate into the substrate to a first depth, and the second trench structure extends from the first surface of the substrate into the substrate to a second depth greater than the first depth,
wherein the third trench structure extends from the first surface of the substrate into the substrate to a third depth greater than the second depth.

19. The image sensing device according to claim 18, further comprising:
an overcoating layer disposed over the first surface of the substrate; and
a plurality of microlenses disposed over the overcoating layer and arranged in a matrix pattern over the first surface of the substrate.

20. The image sensing device according to claim 18, wherein:
the third trench structure includes an air layer.
